(19) United States
(12) Patent Application Publication
(10) Pub. No.: US 2026/0362790 A1
(43) Pub. Date: Nov. 12, 2026

(54) INTEGRATED SCHOTTKY DEVICE AND PREPARATION METHOD THEREOF

(71) Applicant: JIANGSU CORENERGY SEMICONDUCTOR CO., LTD., Suzhou (CN)

(72) Inventors: Tinggang Zhu, Suzhou (CN); Tao Zhang, Suzhou (CN); Yiheng Li, Suzhou (CN); Jihua Li, Suzhou (CN); Leke Wu, Suzhou (CN)

(73) Assignee: JIANGSU CORENERGY SEMICONDUCTOR CO., LTD., Suzhou (CN)

(21) Appl. No.: 19/133,277

(22) PCT Filed: Nov. 29, 2022
(86) PCT No.: PCT/CN2022/134885

§ 371 Date: May 28, 2025

(51) Int. Cl. H10D 84/80; H10D 8/01; H10D 8/25; H10D 8/60; H10D 30/01; H10D 30/47; H10D 62/10; H10D 62/824; H10D 62/832; H10D 62/85; H10D 64/27; H10D 84/01; H10D 89/60

(52) U.S. Cl. CPC H10D 84/811; H10D 8/051; H10D 8/60; H10D 30/015; H10D 30/475; H10D 62/824; H10D 62/8325; H10D 62/8503; H10D 64/411; H10D 84/0107; H10D 89/611; H10D 8/25; H10D 62/103

(57) ABSTRACT

Disclosed in the present invention are an integrated Schottky device and a preparation method. The device comprises a diode unit, a depletion-mode device and a bidirectional cut-off protection unit, wherein a source of the depletion-mode device is cascaded with a negative electrode of the diode unit, the source of the depletion-mode device is cascaded with the bidirectional cut-off protection unit, a gate of the depletion-mode device is connected to a positive electrode of the diode unit, and the bidirectional cut-off protection unit is arranged between two ends of the diode unit. In the present disclosure, the diode unit, the depletion-mode device and the bidirectional cut-off protection unit are integrated to form a Schottky integrated device, which has both a low switch-on voltage drop and a small reverse recovery charge, and the low-voltage diode is protected from the impact of a voltage spike.

### CROSS REFERENCE TO RELATED APPLICATIONS

This application is the U.S. National Phase of PCT/CN2022/134885 filed Nov. 29, 2022, the entire contents of which is incorporated herein by reference in its entirety.

### TECHNICAL FIELD

The present disclosure relates to the field of diodes, in particular to an integrated Schottky device and a preparation method thereof.

### BACKGROUND

In the power conversion of high-power AC-DC, a PFC circuit is generally adopted during input to correct an input power factor and reduce pollution of input harmonics to a power grid, as shown in FIG. 10, D1 to D4 are input rectifier bridges which rectify an input AC signal into a steamed bun wave DC signal, L1 is a PFC energy storage inductor, S1 is a main switch tube, D5 is a PFC boost diode, Co is a PFC output energy storage capacitor, and RL is an output load.

When PFC works in a CCM mode, if D5 selects an ordinary diode, which will generate reverse recovery loss and reverse recovery current during reverse cut-off, great loss is generated, system efficiency is not high and a large heat sink is needed to help dissipate heat. Therefore, D5 generally selects a high-voltage ultra-fast recovery diode or a SiC diode. However, the diode will also cause conduction loss due to forward conduction voltage drop.

If D5 selects an ultra-fast recovery diode, D5 still has reverse recovery charge and the loss is still large when D5 works at a high frequency; SiC has a very small reverse recovery charge, but SiC is expensive with a high cost; at the same time, the conduction voltage drop of high-voltage ultra-fast recovery diode and SiC diode is very high, which is generally 1.5V or even higher, which is higher than the voltage drop of ordinary diodes (for example, 0.5-0.7 V).

The disclosure of the above background is merely used to assist in understanding the inventive concept and technical solutions of the present application. The background does not necessarily belong to the prior art of the present application, and does not necessarily provide technical guidance. In the absence of clear evidence proving that the above content has been disclosed before the filing date of the present application, the above background art should not be used to evaluate the novelty and inventiveness of the present application.

### SUMMARY

The purpose of the present application is to provide an integrated Schottky device which can reduce high-voltage conduction voltage drop and synchronously suppress reverse recovery charge.

To achieve the above purpose, the present application adopts the following technical solutions:
an integrated Schottky device includes a diode unit, a depletion-mode device and a bidirectional cut-off protection unit, wherein a source of the depletion-mode device is cascaded with a negative electrode of the diode unit, the source of the depletion-mode device is cascaded with the bidirectional cut-off protection unit, a gate of the depletion-mode device is connected with a positive electrode of the diode unit, and the bidirectional cut-off protection unit is arranged between two ends of the diode unit; and
the diode unit, the depletion-mode device and the bidirectional cut-off protection unit are integrated into a Schottky integrated device, a drain of the depletion-mode device constitutes a cathode of the Schottky integrated device, and the positive electrode of the diode unit constitutes an anode of the Schottky integrated device.

Further, based on any one of the technical solutions or a combination of multiple technical solutions mentioned above, the bidirectional cut-off protection unit is a circuit in which a diode element and a Zener diode are connected in series, wherein a negative electrode of the Zener diode is connected with a negative electrode of the diode element.

Further, based on any one of the technical solutions or a combination of multiple technical solutions mentioned above, the bidirectional cut-off protection unit is a MOSFET device, wherein a drain of the MOSFET device is connected with the source of the depletion-mode device and the negative electrode of the diode unit, and
a source of the MOSFET device is connected with the positive electrode of the diode unit, and a gate of the MOSFET device is connected with the source thereof in short circuit.

Further, based on any one of the technical solutions or a combination of multiple technical solutions mentioned above, the bidirectional cut-off protection unit is a low-voltage MOSFET device with a reverse recovery charge lower than 80 nC, and the diode unit is a MOSFET body diode.

Further, based on any one of the technical solutions or a combination of multiple technical solutions mentioned above, the bidirectional cut-off protection unit is a bidirectional cut-off discharge load, and the discharge load is connected in parallel with the diode unit.

Further, based on any one of the technical solutions or a combination of multiple technical solutions mentioned above, the depletion-mode device is a depletion-mode GaN device or a depletion-mode SiC device.

Further, based on any one of the technical solutions or a combination of multiple technical solutions mentioned above, the diode unit is a low-voltage Schottky diode device with a conduction voltage drop less than 0.71 V.

According to another aspect of the present application, a method for preparing an integrated gallium nitride Schottky device is provided, including the following steps:
growing a GaN layer, an AlGaN layer and a passivation layer sequentially on a substrate from bottom to top;
etching from the passivation layer downwards to the GaN layer to form a plurality of grooves, and arranging a cathode electrode, a source electrode, and a drain electrode of the Schottky diode in the grooves respectively, and making the cathode electrode conductively connected with the source electrode;
etching from the passivation layer downwards to the AlGaN layer to form a groove, and placing an anode electrode of the Schottky diode in the groove; and
growing a gate electrode on the passivation layer, and making the gate electrode conductively connected with the anode electrode.

Further, based on any one of the technical solutions or a combination of multiple technical solutions mentioned above, the source electrode, the drain electrode, and the cathode electrode and the anode electrode of the Schottky diode are all interdigital electrodes, wherein the source electrode is interdigitated with the drain electrode, and the cathode electrode is interdigitated with the anode electrode of the diode; and
the gate electrode is arranged in an S shape between the source electrode and the drain electrode, and a tail end of the gate electrode extends to be connected with the anode electrode of the Schottky diode.

Further, based on any one of the technical solutions or a combination of multiple technical solutions mentioned above, the method provided by the present application also includes:
preparing a bidirectional cut-off protection unit, wherein the bidirectional cut-off protection unit is a circuit in which a diode element and a Zener diode are connected in series, wherein a negative electrode of the Zener diode is connected with a negative electrode of the diode element; or the bidirectional cut-off protection unit is a MOSFET device, and a gate of the MOSFET device is connected with a source thereof in short circuit; and
conductively connecting one end of the bidirectional cut-off protection unit with the source electrode and the cathode electrode of the Schottky diode, and conductively connecting the other end of the bidirectional cut-off protection unit with the anode electrode of the Schottky diode to obtain an integrated finished device.

The technical solutions provided in the present application have the following beneficial effects:
a. a unidirectional conduction function is realized by using a depletion-mode device, a low-voltage diodes, and a bidirectional cut-off protection circuit, and an integrated Schottky diode integrated device is integrated which has a conduction voltage drop much lower than that of SiC or high-voltage ultra-fast recovery diodes;
b. selecting an appropriate low-voltage diode (such as a Schottky diode) and an appropriate depletion-mode device (such as a depletion-mode gallium nitride device) can realize that the integrated device has an overall reverse recovery charge of close to zero or has a lower reverse recovery charge; and
c. the bidirectional cut-off circuit protects a low-voltage diode from the impact of voltage spike and meanwhile would not introduce reverse recovery charge.

### BRIEF DESCRIPTION OF THE DRAWINGS

In order to more clearly illustrate the technical solutions in the embodiments of the present application or in the prior art, the accompanying drawings required to be used in the description of the embodiments or the prior art will be briefly introduced below. Apparently, the accompanying drawings described below are merely some embodiments recorded in the present application. For those skilled in the art, other drawings can be obtained according to these drawings without any creative effort.

FIG. 1 is a schematic diagram of a first circuit structure of an integrated Schottky device for synchronously suppressing conduction voltage drop and reverse recovery charge provided by an exemplary embodiment of the present application;

FIG. 2 is a schematic diagram of a second circuit structure of an integrated Schottky device for synchronously suppressing conduction voltage drop and reverse recovery charge provided by an exemplary embodiment of the present application;

FIG. 3 is a schematic diagram of a third circuit structure of an integrated Schottky device for synchronously suppressing conduction voltage drop and reverse recovery charge provided by an exemplary embodiment of the present application;

FIG. 4 is a structural schematic diagram of a semi-finished product obtained in a first step of a method for preparing an integrated gallium nitride Schottky device provided by an exemplary embodiment of the present application;

FIG. 5 is a structural schematic diagram of a semi-finished product obtained in a second step of a method for preparing an integrated gallium nitride Schottky device provided by an exemplary embodiment of the present application;

FIG. 6 is a structural schematic diagram of a semi-finished product obtained in a third step of a method for preparing an integrated gallium nitride Schottky device provided by an exemplary embodiment of the present application;

FIG. 7 is a structural schematic diagram of a semi-finished product obtained in a fourth step of a method for preparing an integrated gallium nitride Schottky device provided by an exemplary embodiment of the present application;

FIG. 8 is a structural schematic diagram of an integrated device obtained in a fifth step of a method for preparing an integrated gallium nitride Schottky device provided by an exemplary embodiment of the present application,

FIG. 9 is a schematic diagram of electrode distribution of an integrated device after five steps provided by an exemplary embodiment of the present application;

FIG. 10 is a structural schematic diagram of a power conversion circuit with a PFC boost diode in the prior art.

wherein reference numerals include: 1—diode unit, 2—depletion-mode device, 3—bidirectional cut-off protection unit, 41—GaN layer, 42—AlGaN layer, 43—passivation layer, 51—cathode electrode, 52—source electrode, 53—drain electrode, 54—anode electrode, 55—gate electrode.

### DETAILED DESCRIPTION OF EMBODIMENTS

In order that those skilled in the art can better understand the solutions of the present application, the technical solutions in the embodiments of the present disclosure will be clearly and completely described below in combination with the accompanying drawings in the embodiments of the present application. Apparently, the described embodiments are merely a part but not all of the embodiments of the present application. Based on the embodiments in the present application, all the other embodiments obtained by those skilled in the art without any creative effort should all fall within the protection scope of the present application.

It should be understood that the terms “first”, “second” and the like in the specification and claims and the above drawings of the present application are used to distinguish similar objects, and are not necessarily used to describe a specific order or sequence. It should be understood that the data used in this way can be interchanged where appropriate, so that the embodiments of the present application described herein can be implemented in an order other than those illustrated or described herein. In addition, the terms “including” and “having” and any variations thereof are intended to cover non-exclusive inclusions, for example, a process, method, device, product or equipment that includes a series of steps or units is not necessarily limited to those steps or units clearly listed, but may include other steps or units that are not clearly listed or inherent to these processes, methods, products or equipment.

In one embodiment of the present application, an integrated Schottky device for synchronously suppressing conduction voltage drop and reverse recovery charge is provided, comprising a diode unit 1, a depletion-mode device 2 and a bidirectional cut-off protection unit 3, wherein a source of the depletion-mode device 2 is cascaded with a negative electrode of the diode unit 1, the source of the depletion-mode device 2 is cascaded with the bidirectional cut-off protection unit 3, a gate of the depletion-mode device 2 is connected with a positive electrode of the diode unit 1, and the bidirectional cut-off protection unit 3 is arranged between two ends of the diode unit 1; and
the diode unit 1, the depletion-mode device 2 and the bidirectional cut-off protection unit 3 are integrated into a Schottky integrated device, a drain of the depletion-mode device 2 constitutes a cathode of the Schottky integrated device, and a positive electrode of the diode unit 1 constitutes an anode of the Schottky integrated device.

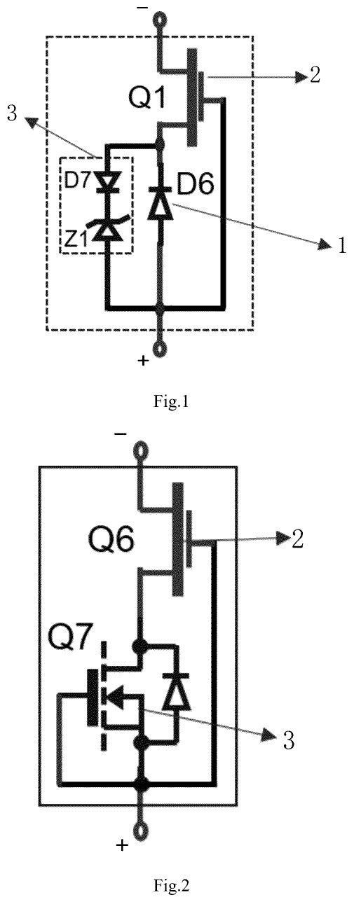

In one embodiment, as shown in FIG. 1, the bidirectional cut-off protection unit 3 is a circuit in which a diode element and a Zener diode are connected in series, wherein the negative electrode of the Zener diode is connected with the negative electrode of the diode element. The depletion-mode device 2 (Q1 in FIG. 1) can be a depletion-mode GaN or a depletion-mode SiC; the diode unit 1 (D6 in FIG. 1) can be a low-voltage Schottky diode or other diodes with relatively low conduction voltage drop and low reverse recovery charge, and Q1 is cascaded with D6. A drain of the depletion-mode device Q1 serves as the cathode (−pin in FIG. 1) of the Schottky integrated device, and an anode of the diode unit D6 serves as the anode (+pin in FIG. 1) of the Schottky integrated device; a source of the depletion-mode device Q1 is short-circuited connected with a cathode of the diode unit D6, and a gate thereof is short-circuited connected with the anode of the diode unit D6. The diode unit D6 is vulnerable to failure caused by a spike voltage when turning off, and therefore, in the present embodiment, a bidirectional cut-off protection unit 3 is connected in parallel with the diode unit D6. The bidirectional cut-off protection unit 3 shown in FIG. 1 includes a diode D7 and a Zener diode Z1. The diode D7 functions to prevent current from flowing through the bidirectional cut-off circuit when the current flows from the +pin to the −pin, thereby avoiding introduction of reverse charge; and the Zener diode Z1 functions to absorb the spike voltage when turning off, thereby protecting the diode unit D6.

When current flows in from the +pin, the diode unit D6 is turned on, and the conduction voltage drop is Vf (for example, 0.5 V), so that a voltage difference of Vf is formed between the gate and the source of the depletion-mode device Q1. Since Q1 is a depletion-mode device, the drain and the source of Q1 are completely turned on, and current flows from the +pin to the-pin, and meanwhile the bidirectional cut-off protection unit 3 prevents the current from flowing through the protection circuit, so the bidirectional cut-off protection unit would not introduce reverse recovery charge; when the current flows in from the-pin, the depletion-mode device Q1 is initially normally turned on, so the current charges a junction capacitor of the diode through a channel of Q1. When the voltage of the junction capacitor reaches a threshold voltage Vth (for example, −10 V) of Q1, that is, the voltage between the gate and the source of Q1 reaches −Vth (i.e., 10 V), Q1 is turned off, and a reverse voltage cut-off state is formed between the −pin and the +pin, so that the current can only flow from the +pin to the −pin, and cannot flow from the −pin to the +pin, thereby forming a unidirectional conduction characteristic. Meanwhile, the bidirectional cut-off protection unit 3 absorbs peak voltage when turning off, thereby protecting the diode unit D6.

During forward conduction, the voltage drop of the diode is low and is only about Vf (for example, 0.5 V), and when the diode is turned on, the depletion-mode device Q1 is completely turned on, so an overall voltage drop is very low (a low-voltage diode is properly selected, and the voltage drop can even be reduced to 0.35 V), which is much lower than the voltage drop of a SiC diode or a high-voltage ultrafast recovery diode; in addition, if the diode unit D6 selects a Schottky diode and the depletion-mode device Ql selects a depletion-mode GaN, the reverse recovery charge of the overall Schottky integrated device can be 0. Therefore, the cascaded diode solution of the present embodiment can achieve low conduction voltage drop and low reverse recovery charge.

In one embodiment, as shown in FIG. 2, Q6 is a high-voltage depletion-mode device, and the bidirectional cut-off protection unit 3 (i.e., Q7 in FIG. 2) is a MOSFET device, wherein the drain. of the MOSFET device is connected with the source of the depletion-mode device 2 and the negative electrode of the diode unit 1, and
the source of the MOSFET device is connected with the positive electrode of the diode unit 1, and the gate and the source of the MOSFET device are short-circuited. Specifically, the bidirectional cut-off protection unit 3 is a low-voltage MOSFET device with a reverse recovery charge lower than 80 nC, and the diode unit 1 is a MOSFET body diode.

When current flows in from the +pin, the body diode of Q7 (i.e., the diode unit 1) is turned on, and the conduction voltage drop is Vf, so that a voltage of Vf is formed between the gate and the source of the depletion-mode device Q6, therefore the drain and the source of the depletion-mode device Q6 are completely connected, and the current flows from the +pin to the −pin; when current flows in from the-pin, the initial state of the depletion-mode device Q6 is normally turned on, so the current charges the junction capacitor of the bidirectional cut-off protection unit Q7 through the channel of the depletion-mode device Q6, and when the voltage of the junction capacitor reaches the threshold voltage Vth of Q6 (for example, −10 V), that is, the voltage between the gate and the source of the depletion-mode device Q6 reaches −Vth (i.e., 10 V), Q6 is turned off, and a reverse voltage cut-off state is formed between the −pin and the +pin. Therefore, the current can only flow from the +pin to the −pin, and cannot flow from the −pin to the +pin, thereby forming a unidirectional conduction characteristic.

During forward conduction, the voltage drop of the body diode of Q7 is low and is only about 0.7 V, and when the body diode is turned on, the depletion-mode device Q6 is completely turned on, so the overall voltage drop is very low, which is much lower than the voltage drop of SiC diodes or high-voltage ultra-fast recovery diodes; since Q7 is a low-voltage MOSFET device, the reverse recovery charge thereof can be smaller than that of high-voltage diodes or high-voltage MOSFET, therefore the present solution reduces the forward conduction voltage drop while ensuring a smaller Qrr (reverse recovery charge).

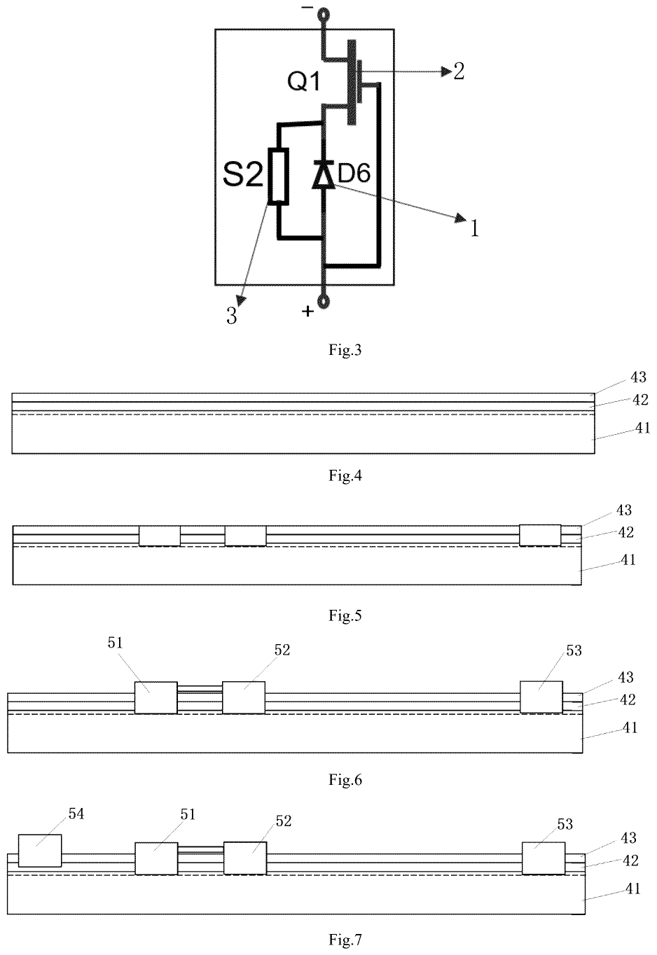

In one embodiment, as shown in FIG. 3, the bidirectional cut-off protection unit 3 is a bidirectional cut-off discharge load, and the discharge load is connected in parallel with the diode unit 1. FIG. 3 provides a cascaded diode solution with a general protection function, and S2 in FIG. 3 can be a bidirectional cut-off protection device to protect the diode unit D6, and when the reverse voltage of the diode unit D6 is higher, S2 can discharge current to prevent the reverse voltage of D6 from continuing to rise or even failing; meanwhile, S2 can adjust a matching degree between the depletion-mode device Q1 and the junction capacitor of the diode unit D6, so that the voltage on the diode unit D6 would not exceed the maximum voltage that D6 can withstand when the overall diode is reversely cut off. In addition, since S2 is bidirectionally cut off, no reverse recovery charge would be introduced.

Based on any of the preceding embodiments, the depletion-mode device 2 is a depletion-mode GaN device or a depletion-mode SiC device; and the diode unit 1 is a low-voltage Schottky diode device with a conduction voltage drop of less than 0.71 V.

The working principle is as follows: during forward conduction of the Schottky integrated device, when the voltage is higher than the conduction voltage drop Vf of the low-voltage Schottky diode, the current is directly conducted since the cathode of the diode is directly linked with the source of a normally-on triode; when the device is reversely turned off, the Schottky diode is in a turn-off state, and a parasitic capacitor of the diode is charged. When the voltage rises to Vgs of the normally-on triode, the normally-on triode enters a turn-off state since the anode of the diode is connected with a gate of the normally-on triode, and finally the withstand voltage of the whole integrated gallium nitride Schottky diode is borne by the respective partial voltage of a built-in front-stage low-voltage Schottky diode and a rear-stage normally-on triode. Compared with traditional silicon devices, Schottky diode devices made of gallium nitride materials have great advantages in performance, which can withstand high reverse voltage while maintaining low resistance of the device during forward operation, thereby greatly reducing the area of semiconductor chips. The heterojunction structure of AlGaN/GaN having two-dimensional electron gas (2DEG) with high-mobility, high electron saturation velocity, and high breakdown electric field strength is an ideal material for fabricating planar gallium nitride Schottky diodes.

The fabricating planar gallium nitride Schottky diodes generally selecting heterojunction structure of AlGaN/GaN would face a problem that the conduction voltage is too high, and the high reverse blocking voltage and low forward conduction voltage of the Schottky diode cannot be satisfied simultaneously. Therefore, embodiments of the present application provide a method for preparing an integrated gallium nitride Schottky device, and a planar gallium nitride Schottky diode with low forward conduction voltage and high reverse blocking voltage is achieved by cascading a low-voltage gallium nitride Schottky diode and a high-voltage gallium nitride normally-on triode on the same gallium nitride epitaxial structure. The preparation method specifically comprises the following steps:
a first step is as shown in FIG. 4, wherein a GaN layer 41, an AlGaN layer 42 and a passivation layer 43 are sequentially grown on a substrate from bottom to top;
a second step is as shown in FIG. 5, wherein etching is performed from the passivation layer 43 downwards to the GaN layer 41 to form a plurality of grooves;
a third step is as shown in FIG. 6, wherein a cathode electrode 51, a source electrode 52, and a drain electrode 53 of the Schottky diode are respectively arranged in the grooves, and the cathode electrode 51 is conductively connected with the source electrode 52;
a fourth step is as shown in FIG. 7, wherein etching is performed from the passivation layer 43 downwards to the AlGaN layer 42 to form a groove, and the anode electrode 54 of the Schottky diode is arranged in the groove; and
a fifth step is as shown in FIG. 8, wherein a gate electrode 55 is grown on the passivation layer 43, and the gate electrode 55 is conductively connected with the anode electrode 54.

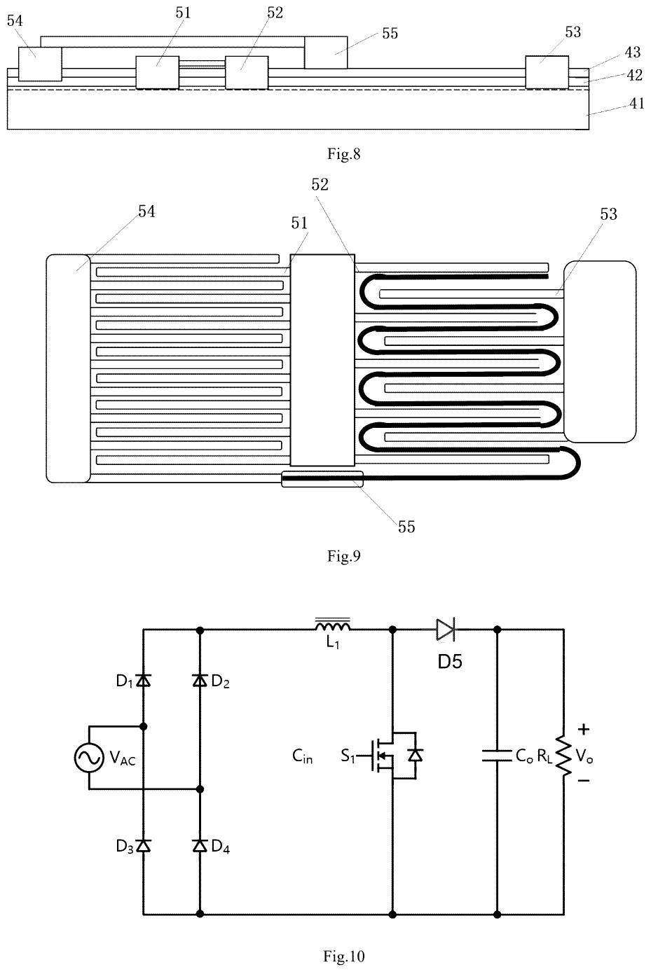

As shown in FIG. 9, the source electrode 52, the drain electrode 53, the cathode electrode 51 and the anode electrode 54 of the Schottky diode are all interdigital electrodes, wherein the source electrode 52 is interdigitated with the drain electrode 53, and the cathode electrode 51 is interdigitated with the anode electrode 54 of the diode; and
the gate electrode 55 is arranged in an S shape between the source electrode 52 and the drain electrode 53, and a tail end of the gate electrode 55 extends to be connected with the anode electrode 54 of the Schottky diode, and the gate electrode 55 is not conductively connected with the cathode electrode 51, the source electrode 52, and the drain electrode 53.

In a specific embodiment of the present application, the method for preparing a gallium nitride Schottky device further comprises:
preparing a bidirectional cut-off protection unit, wherein the bidirectional cut-off protection unit is a circuit in which a diode element and a Zener diode are connected in series, wherein a negative electrode of the Zener diode is connected with a negative electrode of the diode element; or the bidirectional cut-off protection unit is a MOSFET device, and a gate and a source of the MOSFET device are short-circuited; and
conductively connecting one end of the bidirectional cut-off protection unit with the source electrode and the cathode electrode of the Schottky diode, and conductively connecting the other end of the bidirectional cut-off protection unit with the anode electrode of the Schottky diode to obtain an integrated finished device, which has the advantages of synchronously suppressing the conduction voltage drop and the reverse recovery charge. The principle is the same as the above device embodiment and would not be repeated redundantly herein.

It should be noted that, in the present disclosure, relational terms such as first and second are merely used to distinguish one entity or operation from another entity or operation, and do not necessarily require or imply any such actual relationship or order between these entities or operations. Moreover, the terms “include”, “comprise” or any other variants thereof are intended to cover non-exclusive inclusion, so that a process, method, article or equipment including a series of elements includes not only those elements, but also other elements not explicitly listed, or also includes elements inherent to such process, method, article or equipment. In the absence of further restrictions, the elements defined by the sentence “comprise a . . . ” do not exclude the presence of other identical elements in the process, method, article or equipment including the elements.

The above is merely specific embodiments of the present application. It should be pointed out that for those skilled in the art, several improvements and modifications can be made without departing from the principles of the present application. These improvements and modifications should also fall within the protection scope of the present application.

1. An integrated Schottky device, comprising a diode unit, a depletion-mode device and a bidirectional cut-off protection unit, wherein a source of the depletion-mode device is cascaded with a negative electrode of the diode unit, the source of the depletion-mode device is cascaded with the bidirectional cut-off protection unit, a gate of the depletion-mode device is connected with a positive electrode of the diode unit and the bidirectional cut-off protection unit is arranged between two ends of the diode unit; and
the diode unit, the depletion-mode device and the bidirectional cut-off protection unit are integrated into a Schottky integrated device, a drain of the depletion-mode device constitutes a cathode of the Schottky integrated device, and the positive electrode of the diode unit constitutes an anode of the Schottky integrated device.

2. The integrated Schottky device according to claim 1, wherein the bidirectional cut-off protection unit is a circuit in which a diode element and a Zener diode are connected in series, wherein a negative electrode of the Zener diode is connected with a negative electrode of the diode element.

3. The integrated Schottky device according to claim 1, wherein the bidirectional cut-off protection unit is a MOSFET device, wherein a drain of the MOSFET device is connected with the source of the depletion-mode device and the negative electrode of the diode unit; and
a source of the MOSFET device is connected with the positive electrode of the diode unit, and a gate of the MOSFET device is connected with the source thereof in short circuit.

4. The integrated Schottky device according to claim 3, wherein the bidirectional cut-off protection unit is a low-voltage MOSFET device with a reverse recovery charge lower than 80 nC, and the diode unit is a MOSFET body diode.

5. The integrated Schottky device according to claim 1, wherein the bidirectional cut-off protection unit is a bidirectional cut-off discharge load, and the discharge load is connected in parallel with the diode unit.

6. The integrated Schottky device according to claim 1, wherein the depletion-mode device is a depletion-mode GaN device or a depletion-mode SIC device.

7. The integrated Schottky device according to claim 1, wherein the diode unit is a low-voltage Schottky diode device with a conduction voltage drop less than 0.71 V.

8. A method for preparing the integrated Schottky device according to claim 1, comprising the following steps:
growing a GaN layer, an AlGaN layer and a passivation layer sequentially on a substrate from bottom to top;
etching from the passivation layer downwards to the GaN layer to form a plurality of grooves, and arranging a cathode electrode, a source electrode, and a drain electrode of the Schottky diode in the grooves respectively, and making the cathode electrode conductively connected with the source electrode;
etching from the passivation layer downwards to the AlGaN layer to form a groove, and placing an anode electrode of the Schottky diode in the groove; and
growing a gate electrode on the passivation layer, and making the gate electrode conductively connected with the anode electrode.

9. The method according to claim 8, wherein the source electrode, the drain electrode, and the cathode electrode and the anode electrode of the Schottky diode are all interdigital electrodes, wherein the source electrode is interdigitated with the drain electrode, and the cathode electrode is interdigitated with the anode electrode of the diode; and
the gate electrode is arranged in an S shape between the source electrode and the drain electrode, and a tail end of the gate electrode extends to be connected with the anode electrode of the Schottky diode.

10. The method according to claim 8, further comprising:
preparing a bidirectional cut-off protection unit, wherein the bidirectional cut-off protection unit is a circuit in which a diode element and a Zener diode are connected in series, wherein a negative electrode of the Zener diode is connected with a negative electrode of the diode element;
or the bidirectional cut-off protection unit is a MOSFET device, and a gate of the MOSFET device is connected with a source thereof in short circuit; and
conductively connecting one end of the bidirectional cut-off protection unit with the source electrode and the cathode electrode of the Schottky diode, and conductively connecting the other end of the bidirectional cut-off protection unit with the anode electrode of the Schottky diode, to obtain an integrated finished device.
